(19) United States
(12) Patent Application Publication
(10) Pub. No.: US 2016/0353613 A1
(43) Pub. Date: Dec. 1, 2016

(54) HYBRID COOLING FOR COMPUTER SYSTEMS

(71) Applicant: Quanta Computer Inc., Taoyuan City (TW)

(72) Inventors: Chao-Jung CHEN, Taoyuan City (TW); Chih-Ming CHEN, Taoyuan City (TW); Yi-Chieh CHEN, Taoyuan City (TW)

(21) Appl. No.: 14/723,135

(22) Filed: May 27, 2015

(51) Int. Cl. H05K 7/20; H05K 7/14

(52) U.S. Cl. CPC H05K 7/20772; H05K 7/1488; H05K 7/20727

(57) ABSTRACT

In some implementations, a hybrid cooling apparatus can be used to cool computing components within a computing device. For example, the apparatus can comprise a plurality of conductors coupled at one end to a plurality of heat generating computing components. The plurality of conductors can be coupled at another end to a liquid cooling rack. The liquid cooling rack can comprise a radiator, and the plurality of conductors can be coupled to the liquid cooling rack at the radiator. The liquid cooling rack can be adapted to cycle cold liquid coolant through the radiator. Heat generated by the computing components is conducted through the conductors to the radiator and dissipated by the cold liquid coolant.

### TECHNICAL FIELD

The disclosure generally relates to cooling apparatuses and systems for cooling computing components within a server.

### BACKGROUND

Conventionally, computing components within a computing device (e.g., a server, server rack, etc.) generate a considerable amount of heat. If left uncooled, the computing components can overheat and malfunction or fail. In relation to servers, overheating and malfunction of computing components can lead to undesirable interruptions in service to users. Currently, cooling fans, heat sinks, and the like are typically used for cooling computing components. However, as the wattage of computing components increase, the heat generated by the components can exceed the ability of the cooling fans to effectively cool the computing device.

### SUMMARY

In some implementations, a hybrid cooling apparatus can be used to cool computing components within a server. For example, the hybrid cooling apparatus can utilize both liquid and air cooling mechanisms. In some implementations, the apparatus can comprise a plurality of conductors coupled at one end to a plurality of heat generating computing components. The plurality of conductors can be coupled at another end to a liquid cooling rack. The liquid cooling rack can comprise a radiator, and the plurality of conductors can be coupled to the liquid cooling rack at the radiator. In some implementations, the conductors can be inserted into the cooling rack such that the conductors are in direct contact with the liquid coolant. The liquid cooling rack can be adapted to cycle liquid coolant through the radiator. Heat generated by the computing components is conducted through the conductors to the radiator and dissipated by the liquid coolant.

Particular implementations provide at least the following advantages: hybrid cooling of computing components increases efficiency of cooling elements; computing elements are hot-swappable while remaining cooled; liquid cooling occurs outside of server, reducing risk of liquid coolant leakage onto computing components.

Details of one or more implementations are set forth in the accompanying drawings and the description below. Other features, aspects, and potential advantages will be apparent from the description and drawings, and from the claims.

### DESCRIPTION OF DRAWINGS

FIG. 1 is an isometric view of a server apparatus comprising a hybrid cooling apparatus.

FIG. 2A is an isometric view of a hybrid cooling apparatus.

FIG. 2B is an alternate isometric view of the hybrid cooling apparatus in FIG. 2A.

FIG. 2C is a top view of the hybrid cooling apparatus in FIG. 2A.

FIG. 2D is an alternate top view of the hybrid cooling apparatus in FIG. 2A.

Like reference symbols in the various drawings indicate like elements.

### DETAILED DESCRIPTION

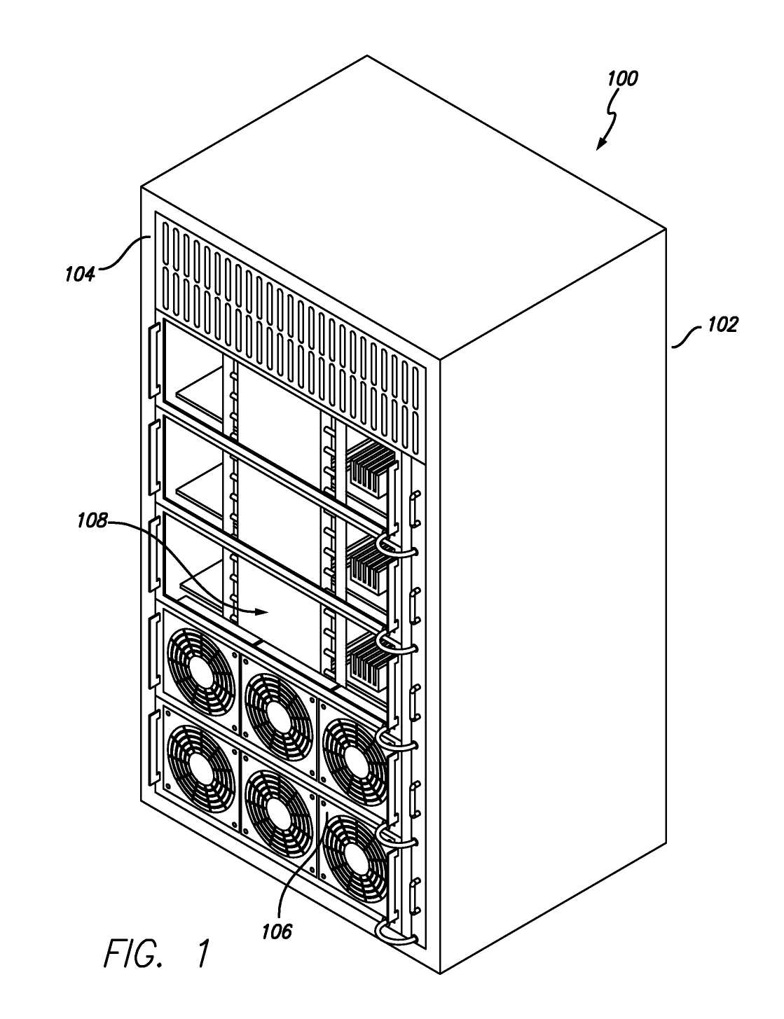

FIG. 1 illustrates an example server rack 100 including a hybrid cooling system. For example, a hybrid cooling system comprising a heat conductive portion and a liquid cooling portion can be used to cool heat-generating computing elements within server rack 100. For example, the heat conductive portion (e.g., heat pipes) can transfer the heat generated by the computing components from the computing components to the liquid cooling portion, where the heat is dissipated at the liquid cooling portion. As such, the computing components can be efficiently and effectively cooled to prevent overheating and malfunction of the computing components.

In some implementations, server rack 100 can comprise front side 102 and rear side 104. Rear side 104 can comprise a plurality of cooling fans 106 and liquid cooling rack 108. Cooling fans 106 can be any cooling fan known in the art that is used for cooling. In some implementations, cooling fans 106 can be located at rear 104 of server rack 100. In some implementations, cooling fans 106 can be located at front 102 of server rack 100. In some implementations, liquid cooling rack 108 can be located at rear 104 of server rack 100. Cooling fans 106 and liquid cooling rack 108 can be used in combination to cool computing components housed within server rack 100. Liquid cooling rack 108 can comprise components commonly known in the art that are used for liquid cooling in computers. For example, liquid cooling rack 108 can comprise a pump, heat sinks, and inlet and outlet tubes for cycling liquid coolant through the computer in a way that the computer does not get wet.

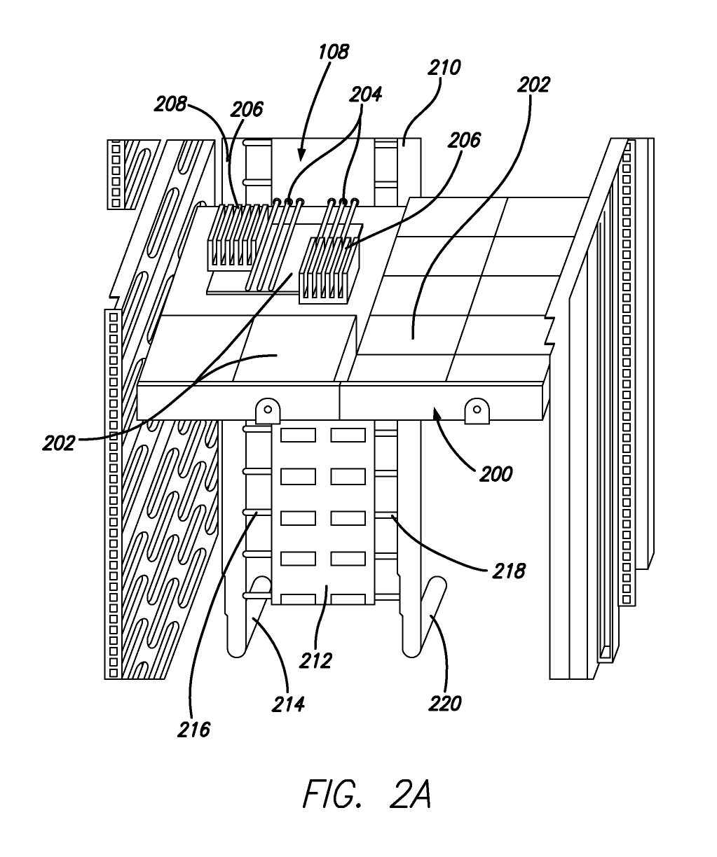

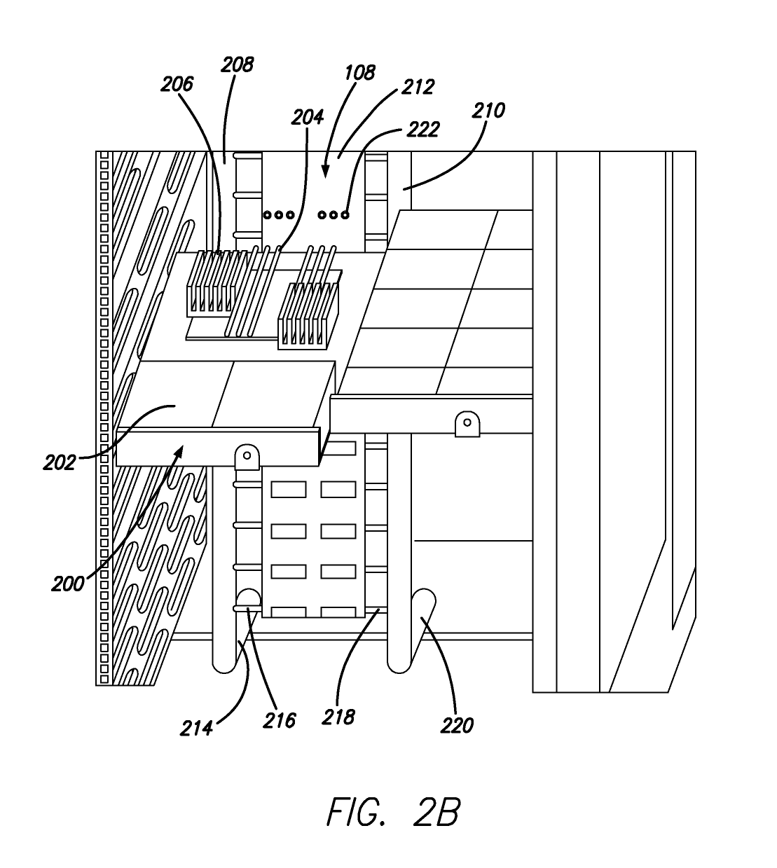

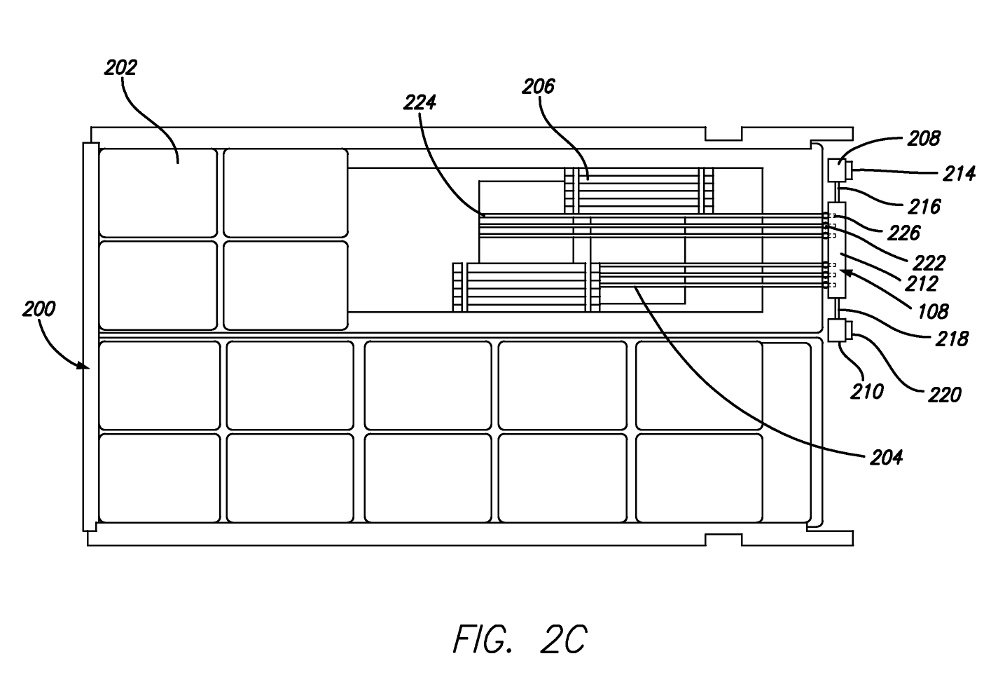

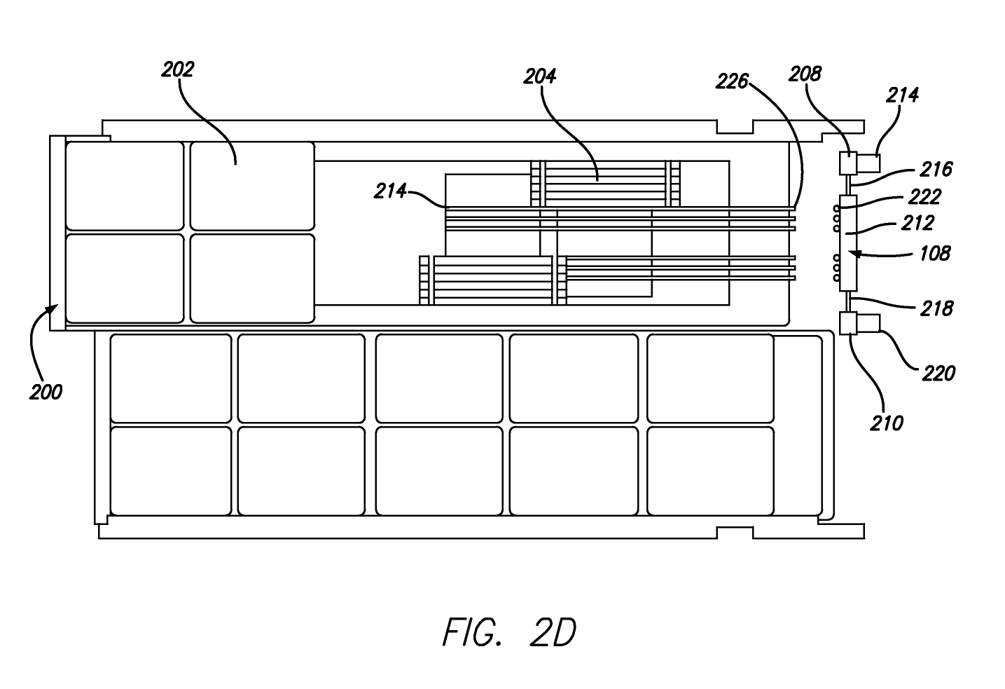

FIG. 2A illustrates sever tray 200 (e.g., server blade, server drawer, etc.) in a closed position. In the closed position, server tray 200 sits about flush with rear 104 of server rack 100. In some implementations, server rack 100 can comprise a plurality of server trays 200. Each server tray 200 can house a plurality of heat-generating computing components 202, including, but not limited to, hard drives, batteries, CPU's, video cards, networking cards, etc.

In some implementations, heat-generating computing components 202 can be coupled to heat sink 206. Heat sink 206 can be any heat sink commonly known in the art for dispersing heat generated by a computing component. For example, heat sink 206 can comprise conductive materials such as copper, aluminum alloys, and composite materials such as silicon carbide. Heat sink 206 can be machined and skived according to means known in the art such that a maximum surface area of the conductive material is exposed to air. For example, heat sink 206 can be designed with a plurality of fins as known in the art for maximizing the surface area of the conductive material. In some implementations, heat sinks 206 can be mounted to computing components 202 as commonly known in the art. For example, heat sink 206 can be mounted directly to the top of a CPU, video card, or other heat generating computing component to dissipate heat generated. Heat sink 206 can facilitate heat dissipation at computing components 202 while also conducting heat outwards to conductive bars 204.

In some implementations, conductive bars 204 can be coupled to computing components 202 to transfer heat generated by computing components 202 to rear 104 of server rack 100. For example, conductive bars 204 can couple to computing components 202 at heat sink 206. In some implementations, conductive bars 204 can be comprised of any metallic heat conductive substance known in the art. For example, conductive bars 204 can be made of copper, aluminum, or the like, and can extend from heat sink 206 to liquid cooling rack 108. In some implementations, conductive bars 204 can comprise heat pipes or heat tubes that are hollow. The hollow interior can be coated with a heat conductive substance as known in the art, to increase conductive efficiency. For example, conductive bars 204 can be coated with thermally conductive epoxy, tape, or other adhesives to increase conductive efficiency.

In some implementations, conductive bars 204 can be grouped into separate groups. For example, a group of three conductive bars 204 can be used. Conductive bars 204 can be equally spaced and have different lengths. For example, a first group of three conductive bars 204 can be longer than a second group of three conductive bars 204 to accommodate different areas of server blade 200. In some implementations the first group can comprise a different number of conductive bars 204 than the second group. For example, the first group can comprise two conductive bars 204, and the second group can comprise five conductive bars 204, or any combination of numbers of conductive bars 204.

In some implementations, liquid cooling rack 108 can comprise inlet tube 208, outlet tube 210, and radiator 212. Cold liquid coolant can be pumped into inlet tubes 208 from inlet 214. For example, water, propylene glycol, or other liquid coolants can be used in radiator 212 to cool conductive bars 212. The cold liquid coolant travels up inlet tube 208 to the top of server rack 100 and across to radiator 212 through inlet radiating pipes 216. At radiator 212, the conductive bars 204 heat the cold liquid coolant. For example, the heat conducted away from the heat-generating components 202 by conductive bars 204 is dissipated from the conductive bars 204 into the liquid coolant. In some implementations, conductive bars 204 are sealed such that the liquid coolant from radiator 212 does not enter conductive bars 204. Thus, the liquid coolant is kept away from sensitive electrical computing components that might be damaged should they come into contact with the liquid coolant. The liquid coolant travels through outlet radiating pipes 218 to outlet tube 210. The heated liquid coolant then exits liquid cooling rack 108 through outlet 220. In some implementations, the heated liquid coolant is cooled down and recirculated through liquid cooling rack 108 as cold liquid coolant. For example, in addition to or instead of radiating the heat at radiator 212, the hybrid cooling system can be coupled to an external condenser (not shown) that cools the liquid coolant before the coolant is recirculated through liquid cooling rack 108. In some implementations, liquid cooling rack 108 can be located external to server rack 100 to reduce risk that electrical components will be exposed to the liquid coolant.

FIG. 2B illustrates server tray 200 in an open position. In the open position, server tray 200 is pulled outwards toward front 102 of server rack 100. In some implementations, server tray 200 can be pulled outside of server rack 100 according to means known in the art relating to server drawers. Server tray 200 can open to allow hot swapping of computing components 202 to/from server tray 200, for example. In some implementations, how swapping of computing components 202 can be done without decoupling conductive bars 204 from computing components 202.

In some implementations, conductive bars 204 can be coupled to radiator 212 through nozzles 222. Nozzles 222 can be sized to frictionally fit with conductive bars 204, and each conductive bar 204 can be coupled to each nozzle 222 individually. In some implementations, nozzle 222 can be adapted to allow conductive bar 204 to be inserted into and removed from radiator 212 such that liquid coolant remains in radiator 212. For example, nozzle 222 can be configured such that nozzle 222 is closed and retains liquid coolant when conductive bar 204 is not inserted into nozzle 222 (i.e., when server tray 200 is in the open position). When conductive bar 204 is inserted into nozzle 222 (i.e., when server tray 200 is in the closed position), nozzle 222 opens to allow conductive bar 204 through nozzle 222 and into radiator 212 so that conductive bar 204 is in direct contact with the liquid coolant. In some implementations, nozzle 222 can comprise water-tight re-sealable apertures as commonly known in the art, such as wafer check valves comprising spring trapdoors. In some implementations, radiator 212 can comprise a water lock for preventing liquid coolant leakage into server rack 100 during insertion and removal of conductive bar 204. For example, the water lock can comprise a chamber where potential spillage of liquid coolant can be contained. The water lock can also comprise a portion that wipes conductive bar 204 as conductive bar 204 slides out of nozzle 222 to remove any coolant adhering to the conductive bar 204 when conductive bar 204 is removed from radiator 212.

FIG. 2C shows a top view of server tray 200 in the closed position. In some implementations, conductive bars 204 can comprise first end 224 and second end 226. First end 224 of conductive bars 204 can be coupled to computing components 202 through heat sink 206. Second end 226 of conductive bars 204 can be coupled to liquid cooling rack 108 at radiator 212.

In some implementations, second end 226 of conductive bars 204 can extend into radiator 212 such that second end 226 of conductive bars 204 directly contacts the cold liquid coolant. For example, nozzle 222 can be adapted to close and open to receive second end 226 of conductive bars 204 to allow second end 226 to directly contact the cold liquid coolant in radiator 212. It is advantageous to directly contact the cold liquid coolant because there will be greater dissipation of heat from conductive bar 204 to the cold liquid coolant, resulting in greater cooling of computing components 202.

FIG. 2D shows a top view of server tray 200 in the open position. In some implementations, conductive bars 204 can be adapted such that second end 226 decouples from radiator 212 in the open position. For example, as server tray 200 is pulled outwards toward front 102 of server rack 100, conductive bars 204 move with server tray 200 and withdraw from the interior of radiator 212. Conductive bars 204 can be fixedly coupled at first end 224 to computing components 202 or heat sink 206 to facilitate this.

In some implementations, nozzles 222 can be adapted to close to prevent the cold liquid coolant from leaking out of radiator 212 when conductive bars 204 are decoupled from radiator. For example, nozzles 222 can comprise wafer check valves as commonly known in the art for preventing fluid from back flowing when a pipe is removably coupled to/from a liquid coolant source. In some implementations, the wafer check valve can comprise a spring loaded door pivotally coupled to an aperture such that a water-tight seal is formed on the aperture. The aperture can be sized to form a water-tight seal on conductive bars 204 when conductive bars 204 are inserted into radiator 212. When conductive bars 204 are removed from radiator, the wafer check valve closes to form a water-tight seal on radiator 212. In some implementations, liquid cooling rack 108 can be spaced apart from server tray 200 such that there is a gap between liquid cooling rack 108 and server tray 200. For example, second end 226 of conductive bars 204 can extend beyond the rear of server tray 200 to couple with radiator 212. It is advantageous to have a gap between liquid cooling rack 108 and server tray 200 because it reduces the possibility of liquid coolant coming into contact with computing components 202 when server tray 200 is opened and closed. In some implementations, the gap can comprise a water lock for capturing coolant that escapes from radiator 212 when conductive bars 204 are withdrawn from radiator 212, as described above. For example, the water lock can comprise an outer door adjacent to server tray 200 and an inner door adjacent to radiator 212. The inner door allows access and entry to radiator 212 for conductive bars 204. The outer door creates a seal against conductive bars 204 and can be adapted to scrape off excess liquid coolant when conductive bars 204 are removed from radiator 212. Liquid coolant that spills out from radiator 212 is collected and trapped in liquid coolant trap (not shown) between the inner door and the outer door of the water lock.

In some implementations, multiple server trays 200 can be coupled to a single liquid cooling rack 108. For example, server rack 100 can comprise a plurality of server trays 200, each server tray 200 being adapted to be pushed/pulled to/from an open and closed position. Each server tray 200 being removably coupled to a single liquid cooling rack 108, according to the above description.

For clarity and simplicity, only a single server rack is described. However, multiple server racks can be supported by the above disclosure. For example, multiple securing clamps can be coupled to a chassis to secure multiple network cards side-by-side according to the disclosure herein.

Numerous specific details are set forth in order to provide a thorough understanding of the embodiments described herein, however, the embodiments described herein can be practiced without these specific details. In other instances, methods, procedures and members have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented. The term “coupled” is defined as connected, whether directly or indirectly through intervening members, and is not necessarily limited to physical connections. The connection can be such that the objects are permanently connected or releasably connected. The term “substantially” is defined to be essentially conforming to the particular dimension, shape or other word that substantially modifies, such that the member need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

Although a variety of examples and other information were used to explain aspects within the scope of the appended claims, no limitation of the claims should be implied based on particular features or arrangements in such examples, as one of ordinary skill would be able to use these examples to derive a wide variety of implementations. For example, the server tray can be used to house components other than computing components, and can be adapted to facilitate coupling and removal of such components from a server rack according to the disclosure above.

Further and although some subject matter may have been described in language specific to examples of structural features and/or method steps, it is to be understood that the subject matter defined in the appended claims is not necessarily limited to these described features or acts. For example, such functionality can be distributed differently or performed in components other than those identified herein. Rather, the described features and steps are disclosed as examples of components of systems and methods within the scope of the appended claims.

What is claimed is:

1. An apparatus comprising:
a computing device including a heat generating component;
a heat conductor having a first end and a second end, the first end coupled to the heat generating component; and
a liquid cooling rack comprising a radiator, the radiator coupled to the heat conductor at the second end, the radiator facilitating dissipation of heat generated by the heat generating component from the heat conductor by exposing the second end of the heat conductor to a cooling liquid.

2. The apparatus of claim 1 wherein the radiator further comprises a resealable aperture adapted to receive the heat conductor, the heat conductor extending through the resealable aperture to directly contact the cooling liquid.

3. The apparatus of claim 2 wherein the heat conductor is adapted to be slidably removable from the liquid cooling rack such that the resealable aperture prevents the cooling liquid from leaking from the radiator after the heat conductor is removed.

4. The apparatus of claim 1 wherein the liquid cooling rack is separated from the computing device by a gap to prevent the cooling liquid from spilling onto the heat generating component when heat conductor is inserted and removed from the liquid cooling rack.

5. The apparatus of claim 1 wherein the heat conductor is coated with a heat conductive substance.

6. The apparatus of claim 5 wherein the heat conductor is hollow with closed ends.

7. The apparatus of claim 1 wherein the heat conductor couples to the heat generating component at a heat sink.

8. An apparatus comprising:
a plurality of conductors coupled at a first end to a plurality of computing components, the plurality of computing components coupled to a motherboard, the plurality of conductors dissipating, at a second end, heat generated by the plurality of computing components;
a liquid cooling rack comprising a first pipe, a second pipe, and a radiator, the first pipe coupled to the radiator through a plurality of inlet radiating pipes and the second pipe coupled to the radiator through a plurality of outlet radiating pipes, the second end of the plurality of conductors being coupled to the liquid cooling rack at the radiator, the radiator facilitating dissipation of heat at the second end by exposing the second end to a cooling liquid; and
the radiator comprising a plurality of resealable apertures adapted to receive the second end of the plurality of conductors, the second end of the plurality of conductors extending through the resealable apertures to directly contact the cooling liquid.

9. The apparatus of claim 8 wherein the plurality of conductors is adapted to be slidably removable from the liquid cooling rack such that the plurality of resealable apertures prevents the cooling liquid from leaking from the radiator after the plurality of conductors is removed.

10. The apparatus of claim 8 wherein the liquid cooling rack is separated from the motherboard by a gap to prevent the cooling liquid from spilling onto the motherboard when the plurality of conductors is inserted and removed from the liquid cooling rack.

11. The apparatus of claim 8 wherein the plurality of conductors have various lengths.

12. The apparatus of claim 11 wherein the plurality of conductors are hollow with closed ends.

13. The apparatus of claim 8 wherein the plurality of conductors couple to the plurality of computing components at a heat sink.

14. A system comprising:
a plurality of conductors comprising a first end and a second end, the plurality of conductors coated with a heat conductive substance;
a slidable server rack comprising a plurality of computing components that generate heat, the plurality of computing components coupled to a motherboard, the plurality of conductors coupled at the first end to the plurality of computing components, the plurality of conductors dissipating, at the second end, heat generated by the plurality of computing components at the first end; and
a liquid cooling rack external to the server rack comprising a first pipe, a second pipe, and a radiator, the first pipe coupled to the radiator through a plurality of inlet radiating pipes and the second pipe coupled to the radiator through a plurality of outlet radiating pipes, the second end of the plurality of conductors being coupled to the liquid cooling rack at the radiator, the radiator facilitating dissipation of heat at the second end by exposing the second end to a cooling liquid.

15. The system of claim 14 wherein the radiator further comprises a plurality of resealable apertures adapted to receive the second end of the plurality of conductors, the second end of the plurality of conductors extending through the resealable apertures to directly contact the cooling liquid.

16. The system of claim 15 wherein the plurality of conductors is adapted to be slidably removable from the liquid cooling rack such that the plurality of resealable apertures prevents the cooling liquid from leaking from the radiator after the plurality of conductors is removed.

17. The system of claim 14 wherein the liquid cooling rack is separated from the motherboard by a gap to prevent the cooling liquid from spilling onto the motherboard when the plurality of conductors is inserted and removed from the liquid cooling rack.

18. The system of claim 14 wherein the plurality of conductors have various lengths.

19. The system of claim 18 wherein the plurality of conductors are hollow with closed ends.

20. The system of claim 14 wherein the plurality of conductors couple to the plurality of computing components at a heat sink.
